(19) United States
(12) Patent Application Publication
(10) Pub. No.: US 2025/0372459 A1
(43) Pub. Date: Dec. 4, 2025

(54) INSPECTION SYSTEM FOR BONDING LENSES TO IMAGE SENSORS

(71) Applicant: ASMPT Singapore Pte. Ltd., Singapore (SG)

(72) Inventors: Yiu Chung LAM, Hong Kong SAR (CN); Ka Shing KWAN, Singapore (SG); Chun Ben CHENG, Hong Kong SAR (CN); Po Lam AU, Hong Kong SAR (CN)

(21) Appl. No.: 18/675,376

(22) Filed: May 28, 2024

(51) Int. Cl. H01L 21/66; G01B 11/00; G01B 11/27; H01L 27/146

(52) U.S. Cl. CPC H01L 22/20; G01B 11/002; G01B 11/272; H10F 39/024

(57) ABSTRACT

A bonding system for bonding a lens to an image sensor includes an inspection system for inspecting position and inclination of the lens and/or the image sensor to improve alignment therebetween during a bonding process. The inspection system includes an optical device configured to inspect a position of the lens and/or image sensor, a sensing device configured to inspect an inclination of the lens and/or image sensor relative to a reference plane, and an optical arrangement arranged to direct a light beam reflected from the lens and/or image sensor to both the optical device and the sensing device, for conducting concurrent inspection of the position and inclination of the lens and/or image sensor by the optical device and the sensing device respectively.

### FIELD OF THE INVENTION

The invention generally relates to aligning a lens with an image sensor during a bonding process, and more specifically to an inspection system for concurrently performing position and tilt measurements on the lens or the image sensor to improve alignment between the lens and the image sensor during the bonding process.

### BACKGROUND

In the assembly of complementary metal oxide semiconductor (CMOS) image sensor (CIS) camera modules, a lens is typically bonded to an image sensor. The lens is mounted on a lens holder that is to be held by a bond head during the bonding process. The performance of the bonding process, including accuracy and repeatability, depends on the correct alignment being attained between the image sensor and the lens. This alignment may in turn be influenced by the actual position and tilt of the image sensor when it is bonded to a substrate and the lens when it is held by a bond head during the bonding process, as well as the uniformity of adhesive layers formed between the image sensor and the lens. Hence, conducting position inspection and tilt measurement on both the image sensor and the lens before bonding is important to ensure good bonding quality and performance of the camera module. Furthermore, measuring the inclination of an optical path formed between the lens and the image sensor after bonding may be conducted to analyze the quality of the bonded packet.

However, the inspections of position and tilt of the image sensor and lens in conventional bonding processes are typically performed on separate platforms. Specifically, position inspection is conducted in-situ by an optical device included in the bonding system, whereas tilt measurements are performed by a measuring device external to the bonding system, such as a Z-scope located at a separate platform. This leads to low efficiency of the bonding process since it is time-consuming to transfer the substrate on which the image sensor is bonded from the bonding platform to a platform for tilt measurement. Also, a complicated calibration process is required to compensate for measurement errors caused by the separation of the measurement modules.

It would therefore be beneficial to provide an inspection system for inspecting the position and tilt of the lens and/or the image sensor before or after bonding to improve the alignment between the lens and the image sensor, thereby effectively solving the aforementioned issues encountered in prior art bonding processes.

### SUMMARY OF THE INVENTION

It is thus an object of the invention to seek to provide an inspection system to be included in a bonding platform for inspecting position and tilt of a lens and/or image sensor concurrently before or after bonding. The inspection system may be configured to measure the position and tilt of the image sensor concurrently prior to bonding or measure the position and tilt of a bonded package of the lens and the image sensor after bonding, or to work with a bond head of a bonding system for measuring the position and tilt of the lens to align the lens with respect to the image sensor prior to bonding or conducting dispensing with a dispenser of the bonding system for evenly dispensing adhesive material onto a bonding surface of the image sensor prior to bonding.

According to a first aspect of the present invention, there is provided a bonding system for bonding a lens to an image sensor, the bonding system comprising an inspection system. The inspection system includes an optical device configured to inspect a position of the lens and/or image sensor, a sensing device configured to inspect an inclination of the lens and/or image sensor relative to a reference plane, and an optical arrangement arranged to direct a light beam reflected from the lens and/or image sensor to both the optical device and the sensing device, for conducting concurrent inspection of the position and inclination of the lens and/or image sensor by the optical device and the sensing device respectively. It should be noted that the position and inclination of the lens and/or image sensor include the position and inclination of a bonded package after the lens is bonded to the image sensor.

According to a second aspect of the present invention, there is provided a bonding method for bonding a lens to an image sensor. The bonding method includes concurrently inspecting a position and an inclination of the image sensor with a first inspection system, concurrently inspecting a position and an inclination of the lens with a second inspection system, wherein each of the first and second inspection system includes an optical device for inspecting the position of the lens and/or the image sensor, a sensing device for inspecting the inclination of the lens and/or the image sensor and an optical arrangement arranged to direct a light beam reflected from the lens and/or the image sensor to both the optical device and the sensing device, and adjusting a position and tilting angle of the lens with a bond head that is holding the lens based on the position and inclination of the lens and the image sensor to align the lens with respect to the image sensor before bonding the lens to the image sensor.

In some embodiments of the invention, the bonding method further includes a step of concurrently inspecting a position and an inclination of a bonded package of the image sensor and the lens after bonding.

According to a third aspect of the present invention, there is provided a bonding method for bonding a lens to an image sensor. The bonding method includes concurrently inspecting a position and an inclination of the image sensor with an inspection system, wherein the inspection system includes an optical device for inspecting the position of the image sensor, a sensing device for inspecting the inclination of the image sensor and an optical arrangement arranged to direct a light beam reflected from the image sensor to both the optical device and the sensing device, and controlling a dispensing operation of a dispenser based on the position and inclination of the image sensor so as to form an adhesive layer with a uniform thickness on a bonding surface of the image sensor prior to bonding the lens to the image sensor.

These and other features, aspects, and advantages will become better understood with regard to the description section, appended claims, and accompanying drawings.

### BRIEF DESCRIPTION OF THE DRAWINGS

Embodiments of the present invention will now be described, by way of example only, with reference to the accompanying drawings, in which:

FIG. 1A is a side view of an inspection system included in a bonding system for bonding a lens to an image sensor according to a first embodiment of the invention;

FIG. 1B is a side view of an inspection system included in a bonding system for bonding a lens to an image sensor according to a second embodiment of the invention;

FIG. 2A to FIG. 2F illustrate a process for bonding the lens to the image sensor with a bonding system including first and second inspection systems for aligning the lens with respect to the image sensor prior to bonding according to one embodiment of the invention;

FIG. 3A to FIG. 3C illustrate a process for dispensing adhesive material on the image sensor with a dispenser and an inspection system before bonding the lens to the image sensor according to one embodiment of the invention.

In the drawings, like parts are denoted by like reference numerals.

### DETAILED DESCRIPTION OF THE PREFERRED EMBODIMENTS OF THE INVENTION

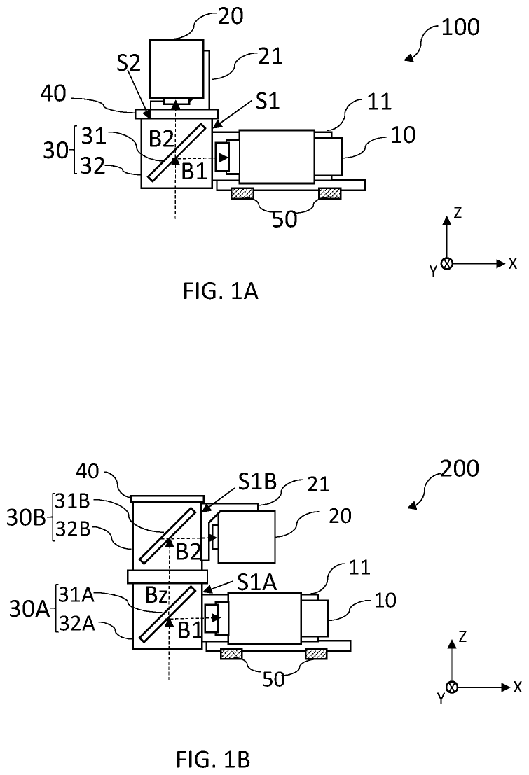

FIG. 1A is a side view of an inspection system 100 included in a bonding system for bonding a lens to an image sensor according to a first embodiment of the invention. The inspection system 100 may be configured to work in association with a bond head included in the bonding system to align the lens with respect to the image sensor before the lens is bonded to the image sensor, or to work in association with a dispenser included in the bonding system to evenly dispense adhesive material on the image sensor before bonding. Furthermore, the inspection system 100A may also be used for inspecting an inclination of the lens relative to the image sensor in the bonded package to identify any tilting of the optical path therebetween after bonding.

Referring to FIG. 1A, the inspection system 100 includes an optical device 10 and a sensing device 20 and an optical arrangement 30. In this embodiment, the optical device 10 and the sensing device 20 are positioned in two directions that are perpendicular to each other, i.e., x-axis and z-axis directions. Specifically, the optical device 10 and the sensing device 20 are arranged such that a first incident light beam B1 received by the optical device 10 is perpendicular to a second incident light beam B2 received by the sensing device 20.

The optical device 10 may include a camera or vision system for inspecting a position of a target object. The target object may include the lens and/or image sensor to be bonded, or the bonded package of the lens and the image sensor. The position of the target object may be represented by coordinate values (X, Y) or (X, Y, Z) in a Cartesian coordinate system and rotary angles (theta) around the z-axis. The sensing device 20 is configured to inspect an inclination of the target object relative to a reference plane. The reference plane may be the plane on which the substrate is positioned, wherein the image sensor is to be or has been bonded to the substrate. This plane may be horizontal and represented by a xy plane in the Cartesian coordinate system. The inclination of the target object may be represented by an inclination angle and inclination direction relative to the reference plane. The sensing device 20 may include a laser displacement sensor, confocal chromatic sensor, interferometer, or laser autocollimator.

The optical arrangement 30 is arranged to direct a light beam reflected from the target object to both the optical device 10 and the sensing device 20 to enable concurrent inspection of position and inclination of the target object by the optical device 10 and the sensing device 20 respectively.

As shown in FIG. 1A, in this embodiment, the optical arrangement 30 includes a beam splitter 31 and a light box 32. The light box 32 includes a container designed to hold the beam splitter 31 and a diffuser to diffuse light from a light source, thereby reducing stray light. The container of the light box 32 may take the form of a rectangular box. The optical device 10 is installed on a mounting frame 11 to face side S1 of the light box 32 such that the first incident light beam B1 along the x-axis direction can be received by the optical device 10. The sensing device 20 is mounted on a mounting frame 21 to face side S2 of the light box 32 such that the second incident light beam B2 along the z-axis direction can be received by the sensing device 20. A surface of side S1 and a surface of side S2 of the light box 32 are perpendicular to each other.

The inspection system 100 also includes a light panel 40 that is mounted between the light box 32 and the sensing device 20. The sensing device 20 may be directly mounted on the light panel 40. Alternatively, the light panel 40 may be mounted on the sensing device 20 which is directly mounted on the light box 32.

In the first embodiment, the optical device 10 and the sensing device 20 of the inspection system 100 are arranged along two directions that are perpendicular to each other, whereas, in other embodiments of the invention, they may be arranged along two parallel directions, e.g., two directions parallel to the x-axis direction.

FIG. 1B shows a side view of an inspection system 200 included in the bonding system for bonding the lens to the image sensor according to a second embodiment of the invention. Compared to the inspection system 100, the inspection system 200 includes a different optical arrangement for directing the light beam reflected from the target object to both the optical device 10 and the sensing device 20. As shown in FIG. 1B, the optical arrangement includes a beam splitting arrangement 30A and a beam directing arrangement 30B mounted on the beam splitting arrangement 30A. The beam splitting arrangement 30A and the beam directing arrangement 30B are arranged in a stack along the z-axis direction. The beam splitting arrangement 30A is configured to generate and direct a first incident light beam into the optical device 10 and the beam directing arrangement 30B is configured to generate and direct a second incident light beam into the sensing device 20. The first and second incident light beams are parallel to each other.

The beam splitting arrangement 30A includes a beam splitter 31A and a light box 32A. The light box 32A includes a container designed to hold the beam splitter 31A and a diffuser to diffuse light from a light source, thereby reducing stray light. The container may be in the form of a rectangular box. The beam splitter 31A is configured to split a light beam reflected from the target object into the first incident light beam B1 along the x-axis direction and a light beam Bz along the z-axis direction and direct the first incident light beam into the optical device 10. The optical device 10 is installed on a mounting frame 11 to face side S1A of the light box 32A such that the first incident light beam B1 along the x-axis direction can be received by the optical device 10. A surface of the side S1A of the light box 32A is perpendicular to the first incident light beam B1.

The beam directing arrangement 30B includes a beam splitter 31B and a light box 32B. The light box 32B includes a container designed to hold the beam splitter 31B and a diffuser to diffuse light from a light source, thereby reducing stray light. The container may be in the form of a rectangular box. The beam splitter 31B is configured to receive the light beam Bz from the beam splitting arrangement 30A along the z-axis direction, direct the light beam Bz to the x-axis direction to generate the second incident light beam B2 and direct the second incident light beam B2 into the sensing device 20. The sensing device 20 is installed on a mounting frame 21 to face side S1B of the light box 32B such that the second incident light beam B2 along the x-axis direction can be received by the sensing device 20. A surface of the side B1 of the light box 32A is perpendicular to the second incident light beam B2.

The inspection system 100B also includes a light panel 40 that is mounted on the light box 32B. Alternatively, the light panel 40 may be mounted on other parts of the bonding system as long as it can provide adequate lighting for the inspection system 100B.

In FIG. 1A and FIG. 1B, both the inspection systems 100 and 200 are arranged as down-look inspection systems for illustration purposes. In use, the down-look inspection system 100 or 200 is positioned above the target object to inspect a position and inclination of the target object. It should be appreciated that the inspection system 100 or 200 may also be arranged as up-look inspection systems for inspecting a target object positioned above the inspection system, e.g., by rotating the inspection systems shown in FIG. 1A and FIG. 1B by 180 degrees around the x-axis. In a bonding system, the inspection system 100 or 200 may be configured to be integrated with a bond head for aligning the lens with respect to the image sensor prior to bonding, or integrated with a dispenser for controlling a dispensing operation of the dispenser so that an adhesive layer having a consistent thickness can be applied on the image sensor before bonding.

Bond Head with Inspection System

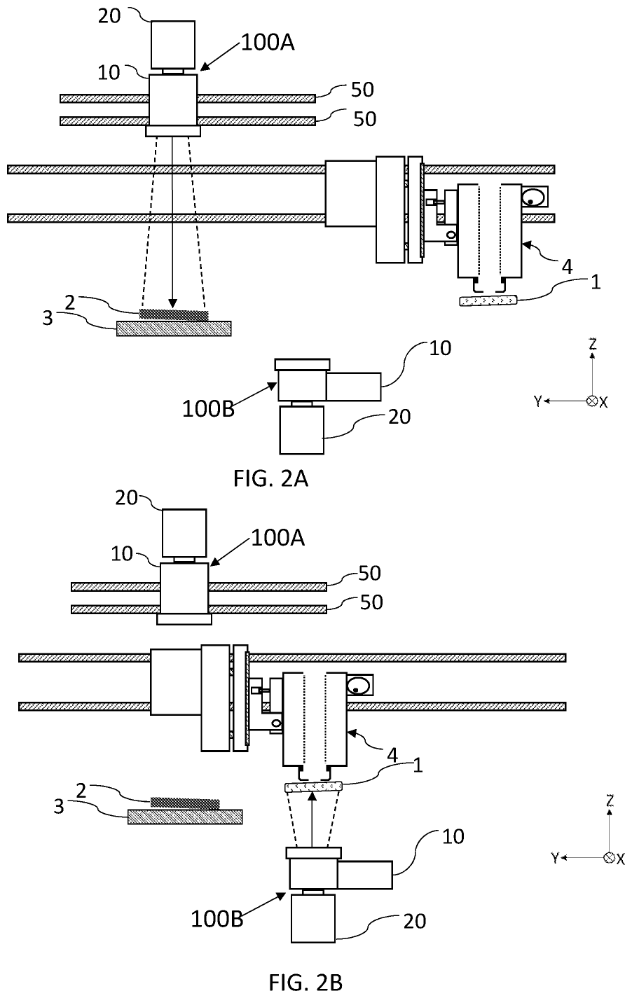

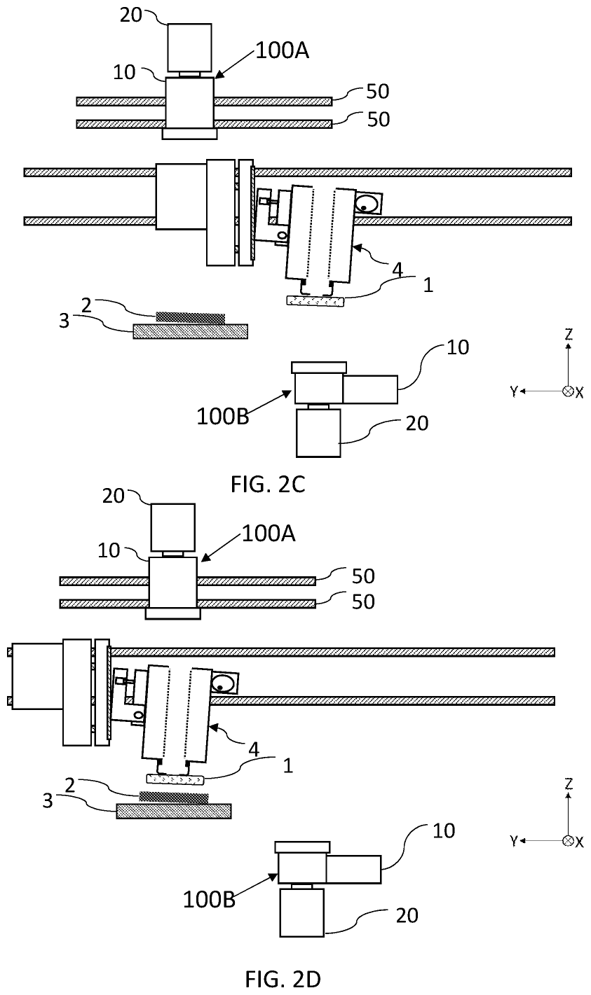

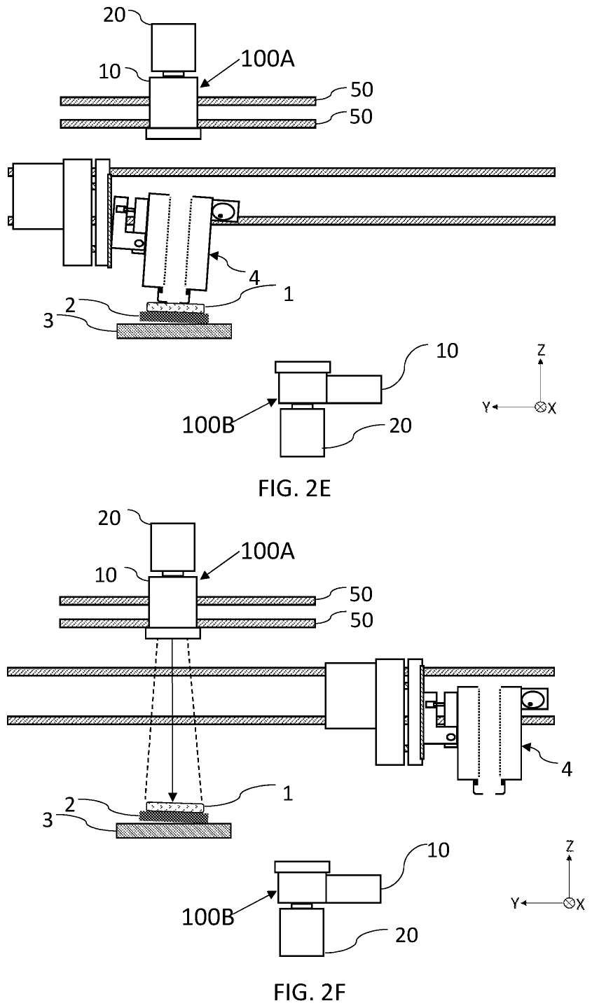

In some embodiments, two inspection systems 100 or 200 may be operated in association with a bond head for bonding a lens to an image sensor which has already been bonded to a substrate. FIGS. 2A to 2F illustrate the process of bonding a lens 1 to an image sensor 2 with a bonding system including first and second inspection systems 100A, 100B for aligning the lens 1 with respect to the image sensor 2 before bonding according to one embodiment of the invention.

Referring to FIGS. 2A to 2F, the first inspection system 100A is arranged as a down-look inspection system for inspecting position and inclination of the image sensor 2 and the second inspection system 100B is arranged as an up-look inspection system for inspecting position and inclination of the lens 1 when it is being held by the bond head 4. The first inspection system 100A is mounted on motion guides 50 along the y-axis direction, while the second inspection system 100B is mounted on motion guides (not shown) along the x-axis direction. it should be noted that the inspection systems 100A, 100B may be mounted on other mounting structures on the platform for bonding as long as the first and second inspection systems 100A, 100B are enabled to inspect the lens 1 and image sensor 2 before or after bonding. The first inspection system 100A includes an optical system 10 for inspecting the position of the image sensor 2 prior to bonding and a sensing device 20 for measuring the tilt of the image sensor 2 prior to bonding, or the inclination of the lens and image sensor comprised in the bonded package after bonding. The optical system 10 may be also used for inspecting the position of the bond head 4 during the bonding. The second inspection system 100B includes an optical system 10 for inspecting the position of the lens 1 and a sensing device 20 for measuring the tilt of the lens 1 when the lens 1 is held by the bond head 4 prior to bonding.

The bonding process will be explained below in detail with reference to FIG. 2A to FIG. 2F.

In Step 1 as shown in FIG. 2A, the first inspection system 100A is operative to inspect the position and inclination of the image sensor 2. Specifically, the optical device 10 of the first inspection system 100A is configured to measure the x, y and theta positions of the image sensor 2 and the sensing device 20 of the first inspection system 100A is configured to measure a tilting direction and tilting angle of the image sensor 2 relative to the xy or horizontal plane on which the substrate 3 is located. The position and tilt measurement results are provided to the bond head 4 to align the lens 1 relative to the image sensor 2 prior to bonding. The x, y and theta positions of the image sensor 2 refer to the x, y coordinate values and the rotary angle around the z-axis of the image sensor 2.

In Step 2 as shown in FIG. 2B, the bond head 4 conveys the lens 1 to a position directly above the second inspection system 100B. The second inspection system 100B is operative to inspect the position and the inclination or tilting direction/angle of the lens 1. Specifically, the optical device 10 of the second inspection system 100B is configured to measure the x, y and theta positions of the lens 1 and the sensing device 20 of the second inspection system 100B is configured to measure the tilting angle and tilting direction of the lens 1 relative to the xy or horizontal plane. The position and tilt measurement results are provided to the bond head 4 for adjusting the position and tilt of the lens 1 relative to the image sensor 2 prior to bonding.

Although in this embodiment, the inspections on the image sensor 2 are conducted before the inspections on the lens, the sequence is only for illustrative purposes. In other embodiments, the position and tilt measurements of the image sensor 2 and the lens 1 may be conducted simultaneously or in some other sequence in combination with other processes.

In Step 3 as shown in FIG. 2C, the bond head 4 adjusts the inclination of the lens 1 relative to the xy or horizontal plane based on the tilt measurement results to ensure that the inclination of the lens 1 is aligned with that of the image sensor 2.

In Step 4 as shown in FIG. 2D, the bond head 4 aligns the position and orientation of the lens 1 with the image sensor 2 by utilizing position measurement results obtained in steps 1 and 2. Specifically, the bond head 4 adjusts the x, y, and theta positions of the lens 1 in accordance with those of the image sensor 2 to achieve alignment between the two components.

It should be noted that the adjustments for position and tilt can be executed in various sequences. For instance, the process may begin with adjusting the position of lens 1 along the x and y axes, followed by tilt adjustments relative to the xy plane, and finally orienting the lens 1 within the xy plane.

In Step 5 as shown in FIG. 2E, the bond head 4 attaches and bonds the lens 1 to the image sensor 2.

In Step 6 as shown in FIG. 2F, the first inspection system 100A is operative to inspect the position and inclination of a bonded package including the lens 1 and the image sensor 2 to identify an optical path formed therebetween. The measurement results are recorded for accuracy analysis.

Dispenser with Inspection System

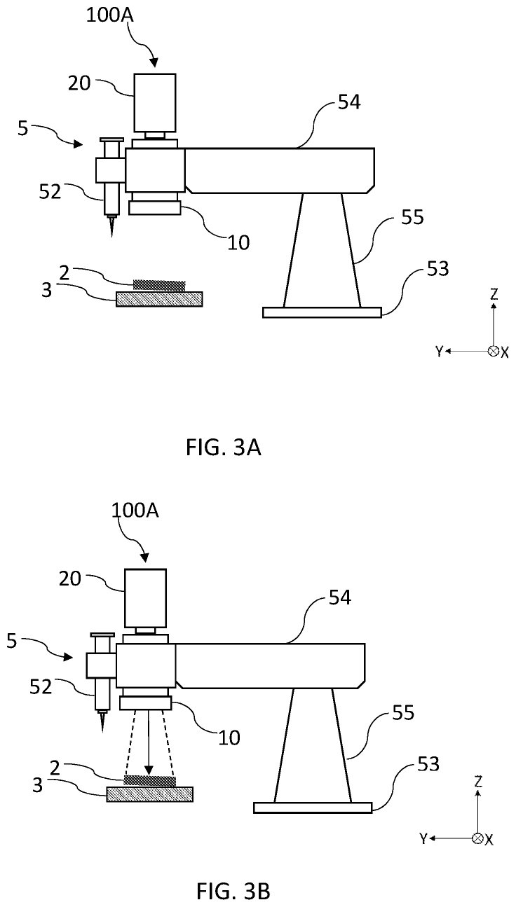

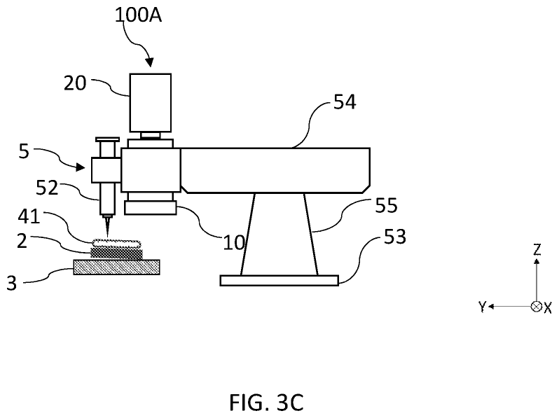

In some embodiments, an inspection system 100 or 200 may be provided to operate in association with a dispenser for dispensing adhesive material onto an image sensor before bonding a lens to the image sensor. FIGS. 3A to 3C illustrate the process of dispensing adhesive material onto the image sensor 2 with a dispenser 5 and an inspection system 100A according to one embodiment of the invention.

Referring to FIG. 3A to FIG. 3C, the optical device 10 of the inspection system 100A is operative to inspect and measure the x, y, and theta positions of the image sensor 2. The sensing device 20 of the inspection system 100A is operative to measure a tilting direction and tilting angle of the image sensor 2 relative to the xy or horizontal plane. The measurement results are utilized to control the dispensing operation of the dispenser 5. In this embodiment, controlling the dispensing operation includes regulating the dispensing levels of the dispenser 5 to ensure that the dispenser 5 is spaced from the image sensor 2 at a regular distance so that the adhesive material dispensed on the image sensor 2 maintains a uniform or consistent thickness. The dispenser 5 incudes a positioning table for positioning a syringe 52 of the dispenser 5 in the x-axis, y-axis and z-axis directions. Specifically, the positioning table may include a X table 53 for positioning the syringe 52 in the x-axis, a Y table 54 for positioning the syringe 52 in the y-axis and a Z table 55 for positioning the syringe 52 in the z-axis. In this embodiment, the inspection system 100A is mounted on the Y-table 54. Alternatively, it may also be mounted on the X-table 53 provided that the inspection system 100A is movable towards the image sensor 2 to perform the inspections thereon.

The dispensing process will be explained below in detail with reference to FIG. 3A to FIG. 3C.

Referring to FIG. 3A, the inspection system 100A is positioned directly above the image sensor 2 to concurrently perform the position and tilt measurements on the image sensor 2.

Referring to FIG. 3B, the inspection system 100A is operative to concurrently measure the position of the image sensor 2 with the optical system 10 and the tilt of the image sensor 2 with the sensing device 20. The measurement results are used to regulate or adjust the dispensing levels of the dispenser 5 during the subsequent dispensing process or operation.

Then, referring to FIG. 3C, the dispenser 5 is operative to dispense adhesive material onto a top surface or bonding surface of the image sensor 2. The dispensing levels of the dispenser 5 are regulated to correspond as close as possible to the position and tilting angle of the image sensor 2 to ensure the amount of the adhesive material dispensed on each target point on the bonding surface of the image sensor 2 is uniform, thereby obtaining an adhesive layer 41 having a consistent thickness on the bonding surface of the image sensor 2. The regulation of the dispensing levels may be performed by raising or lowering the syringe 52 of the dispenser 5 along the z-axis according to the position of each target point on the bonding surface of the image sensor 2 and the tilt of the image sensor 2.

As will be appreciated from the above description, embodiments of the invention provide an inspection system that may be integrated with a bond head and/or a dispenser for bonding a lens to an image sensor. The inspection system includes an optical system, a sensing device, and an optical arrangement that is configured to direct a laser light beam reflected from a target object, e.g., the image sensor or the lens or the bonded package thereof, to both the optical system and the sensing device, thereby enabling the inspection system to concurrently perform position and tilt inspections on the target object. When the inspection system is used to inspect the image sensor during a bonding process, the inspection system is arranged to be a down-look inspection system to conduct position and tilt measurements prior to bonding the lens to the image sensor with the bond head or prior to dispensing adhesive material onto the image sensor. The down-look inspection system may include a down-look sensing device. When the inspection system is used to inspect the lens during a bonding process, the inspection system is further arranged as an up-look inspection system to measure the position and tilt of the lens prior to bonding. The up-look inspection system may include an up-look sensing device. It will be appreciated by a person skilled in the art, the lens may be installed in a lens holder which is held by the bond head during the bonding process.

With the inspection systems provided in the described embodiments of the invention, the bond head is able to effectively address or compensate for any relative position offset and tilt between the lens and the image sensor to be bonded. This is achieved by adjusting the position and tilt of the lens with the bond head based on simultaneous inspections performed on the image sensor through a down-look inspection system and on the lens through an up-look inspection system. Compared to prior art bonding systems, the bond head integrated with the inspection systems can avoid the need to transfer the substrate from a bonding platform to a tilt measurement platform for measuring the inclination of the image sensor before bonding. Therefore complicated software calibration is not required for compensating any translation errors caused by the separation of the measurement modules. Furthermore, the down-look inspection system is also operative to conduct position and tilt measurements on the bonded package after bonding is conducted for further accuracy analysis. As a result, the efficiency and performance of the bonding process can be significantly improved.

Compared to prior art dispensing processes, the inspection system enables the dispenser to achieve dynamic height dispensing by concurrently inspecting the position and tilt of the image sensor. This means that an adhesive layer having consistent thickness can be applied to the top/bonding surface of the image sensor, even if the image sensor is tilted relative to the horizontal plane on which the substrate to which the image sensor has been bonded is located. An adhesive layer with a uniform thickness can also help to ensure alignment between the lens and the image sensor during the bonding process.

Although the present invention has been described in considerable detail with reference to certain embodiments, other embodiments are possible. Therefore, the spirit and scope of the appended claims should not be limited to the description of the embodiments contained herein.

1. A bonding system for bonding a lens to an image sensor, the bonding system comprising an inspection system which comprises:
an optical device configured to inspect a position of the lens and/or image sensor,
a sensing device configured to inspect an inclination of the lens and/or image sensor relative to a reference plane, and
an optical arrangement arranged to direct a light beam reflected from the lens and/or image sensor to both the optical device and the sensing device, for conducting concurrent inspection of the position and inclination of the lens and/or image sensor by the optical device and the sensing device respectively.

2. The bonding system according to claim 1, wherein the optical device is configured to receive a first incident light beam from the optical arrangement and the sensing device is configured to receive a second incident light beam from the optical arrangement, the first and second incident light beams being perpendicular to each other.

3. The bonding system according to claim 2, wherein the optical arrangement includes a beam splitter configured to split the light beam reflected from the lens and/or image sensor into the first incident light beam to be received by the optical device and the second incident light beam to be received by the sensing device respectively.

4. The bonding system according to claim 3, wherein the optical arrangement further includes a light box for holding the beam splitter, the sensing device being mounted to face a first side of the light box and the optical device being mounted to face a second side of the light box, the first side and second side being perpendicular to each other.

5. The bonding system according to claim 4, wherein the light box includes a container designed to hold the beam splitter and a diffuser to diffuse light from a light source.

6. The bonding system according to claim 1, wherein the optical device is configured to receive a first incident light beam from the optical arrangement and the sensing device is configured to receive a second incident light beam from the optical arrangement, the first and second incident light beams being parallel to each other.

7. The bonding system according to claim 6, wherein the optical arrangement includes a beam splitting arrangement and a beam directing arrangement which are arranged in a stack along a direction perpendicular to the first and second incident light beams, the beam splitting arrangement being configured to generate and direct the first incident light beam into the optical device and the beam directing arrangement being configured to generate and direct the second incident light beam into the sensing device.

8. The bonding system according to claim 7, wherein the beam splitting arrangement includes a first beam splitter configured to split the light beam from the lens and/or image sensor to generate and direct the first incident light beam into the optical device.

9. The bonding system according to claim 8, wherein the beam splitting arrangement further includes a first light box for holding the first beam splitter, the optical device being mounted to face a first side of the first light box, a surface of the first side being perpendicular to the first incident light beam.

10. The bonding system according to claim 7, wherein the beam directing arrangement includes a second beam splitter configured to receive a light beam from the beam splitting arrangement, generate and direct the second incident light beam into the sensing device.

11. The bonding system according to claim 10, wherein the beam directing arrangement further includes a second light box for holding the second beam splitter, the sensing device being mounted to face a second side of the second light box, a surface of the second side being perpendicular to the second incident light beam.

12. The bonding system according to claim 1, wherein the inspection system includes a down-look inspection system mounted above the image sensor for inspecting the image sensor before bonding the lens to the image sensor or for inspecting the bonded image sensor.

13. The bonding system according to claim 12, wherein the sensing device of the down-look inspection system includes a tilt measurement sensor for inspecting a tilting angle of the lens and/or image sensor.

14. The bonding system according to claim 12, wherein the down-look inspection system is mounted on a positioning table on which a dispenser for dispensing adhesive fluid on the image sensor is also installed.

15. The bonding system according to claim 1, wherein the inspection system includes an up-look inspection system mounted below the lens when the lens is held by a bond head of the bonding system, for inspecting the lens before bonding the lens to the image sensor.

16. The bonding system according to claim 15, wherein the sensing device of the up-look inspection system includes a tilt measurement sensor for inspecting a tilting angle of the lens being held by the bond head.

17. A bonding method for bonding a lens to an image sensor, the bonding method comprising:
concurrently inspecting a position and an inclination of the image sensor with a first inspection system,
concurrently inspecting a position and an inclination of the lens with a second inspection system, wherein each inspection system includes an optical device for inspecting the position of the lens and/or the image sensor, a sensing device for inspecting the inclination of the lens and/or the image sensor and an optical arrangement arranged to direct a light beam reflected from the lens and/or the image sensor to both the optical device and the sensing device,
adjusting a position and tilting angle of the lens with a bond head that is holding the lens based on the position and inclination of the image sensor and the lens to align the lens with respect to the image sensor before bonding the lens to the image sensor.

18. The bonding method according to claim 17, further comprising:
inspecting position and inclination of the lens and/or the image sensor with the first inspection system after bonding of the lens.

19. A bonding method for bonding a lens to an image sensor, the bonding method comprising:
concurrently inspecting a position and an inclination of the image sensor with an inspection system, wherein the inspection system includes an optical device for inspecting the position of the image sensor, a sensing device for inspecting the inclination of the image sensor and an optical arrangement arranged to direct a light beam reflected from the image sensor to both the optical device and the sensing device, and
controlling a dispensing operation of a dispenser based on the position and a tilting angle of the image sensor so as to form an adhesive layer with a uniform thickness on a bonding surface of the image sensor prior to bonding the lens to the image sensor.
